(19) United States
(12) Patent Application Publication
(10) Pub. No.: US 2025/0210394 A1
(43) Pub. Date: Jun. 26, 2025

(54) MEMBER FOR SEMICONDUCTOR MANUFACTURING EQUIPMENT

(71) Applicant: NGK INSULATORS, LTD., Nagoya-City (JP)

(72) Inventors: Masaki ISHIKAWA, Handa-City (JP); Tatsuya KUNO, Nagoya-City (JP); Taro USAMI, Ginan-Town (JP); Natsuki HIRATA, Nagoya-City (JP); Naoki YAMAMOTO, Handa-City (JP); Yusuke OGISO, Nagakute-City (JP); Seiji NAKAYAMA, Nagoya-City (JP)

(73) Assignee: NGK INSULATORS, LTD., Nagoya-City (JP)

(21) Appl. No.: 18/800,232

(22) Filed: Aug. 12, 2024

Related U.S. Application Data
(63) Continuation of application No. PCT/JP2023/045783, filed on Dec. 20, 2023.

(51) Int. Cl. H01L 21/683; H01L 21/67

(52) U.S. Cl. CPC H01L 21/6833; H01L 21/67017

(57) ABSTRACT

A member for a semiconductor manufacturing equipment, comprising: a ceramic substrate having an upper surface on which a wafer is to be placed and a lower surface; a plug placement hole that vertically penetrates the ceramic substrate and comprises a tapered inner peripheral surface in which an area of an upper opening is larger than an area of a lower opening; a ceramic plug comprising a dense outer peripheral surface and a gas passage penetrating the plug, the ceramic plug being embedded such that the dense outer peripheral surface of the plug is directly fitted to the inner peripheral surface of the plug placement hole; a conductive base plate bonded to the lower surface of the ceramic substrate via a bonding layer; and a gas supply path that passes through the base plate and the bonding layer to supply gas to the gas passage of the ceramic plug.

### CROSS REFERENCE TO RELATED APPLICATIONS

The present invention claims the benefit of priority to International Patent Application PCT/JP2023/45783 filed on Dec. 20, 2023 with the Japanese Patent Office, the entire contents of which are incorporated herein by reference in its entirety.

### FIELD OF THE INVENTION

The present invention relates to a member for a semiconductor manufacturing equipment.

### BACKGROUND OF THE INVENTION

Conventionally, members for semiconductor manufacturing equipment used for holding, temperature control, transporting, or the like of wafers have been known. These types of members for semiconductor manufacturing equipment are also called a wafer placement table, an electrostatic chuck, a susceptor, or the like. Generally, they have the function of applying electrical power for electrostatic adsorption to internal electrodes and adsorbing a wafer using electrostatic force. Some members are known that have a function of controlling the temperature of the wafer by flowing gas between the wafer placement surface and the wafer, which is the object to be adsorbed.

An example of a known member for semiconductor manufacturing equipment includes a ceramic substrate having an upper surface on which a wafer is to be placed, a gas passage portion that vertically penetrates the ceramic substrate, and a conductive base plate bonded to the lower surface of the ceramic substrate.

In such a member for a semiconductor manufacturing equipment, a large potential difference from the wafer may occur, and discharge (insulation breakdown) may occur between the wafer and the base plate via the gas passage portion. For this reason, various techniques for arranging plugs in a gas passage portion have been studied in order to suppress discharge. Plugs are often composed of porous materials. If there is no plug, for example, when gas molecules are ionized by the application of an RF voltage, the generated electrons are accelerated and collide with other gas molecules, causing a glow discharge and eventually an arc discharge. However, if there is a plug, it suppresses the discharge because the electrons hit the plug before colliding with other gas molecules.

Patent Literature 1 proposes a plug having a gas flow passage section that penetrates in flexion a dense main body portion in the thickness direction while being bent. It has also been proposed that at least a portion of the entire length of the gas flow passage section be made porous with insulation properties and gas permeability. In Patent Literature 1, it is described that a plug is fixed to a plug insertion hole using an adhesive material of an insulating resin such as silicone resin, epoxy resin, or acrylic resin.

Patent Literature 2 discloses an electrostatic chuck, comprising a

ceramic dielectric substrate having a first main surface on which an object to be attracted is placed and a second main surface opposite to the first main surface; a base plate that supports the ceramic dielectric substrate and has a gas introduction path; and a first porous portion provided between the base plate and the first main surface of the ceramic dielectric substrate and facing the gas introduction path; characterized in that the ceramic dielectric substrate has a first main surface and a first hole portion located between the first main surface and the first porous portion; the first porous portion has a porous portion having a plurality of pores, and a first dense portion that is denser than the porous portion; and configured such that when projected onto a plane perpendicular to a first direction from the base plate to the ceramic dielectric substrate, the first dense portion and the first hole portion overlap, but the porous portion and the first hole portion do not overlap. According to Patent Literature 2, an adhesive member is provided between the first porous portion and the ceramic dielectric substrate, and a silicone adhesive is described as the adhesive member.

Patent Literature 3 discloses an electrostatic chuck, comprising a ceramic dielectric substrate having a first main surface on which an object to be attracted is placed and a second main surface opposite to the first main surface; a base plate that supports the ceramic dielectric substrate and has a gas introduction path; and a first porous portion provided between the base plate and the first main surface of the ceramic dielectric substrate and facing the gas introduction path; characterized in that the first porous portion has a plurality of sparse portions having a plurality of pores, and a dense portion having a density higher than the density of the sparse portion; each of the plurality of sparse portions extends in a first direction from the base plate toward the ceramic dielectric substrate; the dense portion is located among the plurality of sparse portions; the sparse portion has the holes and a wall portion provided among the holes; and in a second direction substantially perpendicular to the first direction, the minimum dimension of the wall portion is smaller than the minimum dimension of the dense portion. According to Patent Literature 3, when both the first porous portion and the ceramic dielectric substrate are sintered and integrated, the strength of the electrostatic chuck can be improved compared to cases in which adhesive is used therebetween. It is also described that the electrostatic chuck does not deteriorate due to corrosion or erosion of the adhesive.

Patent Literature 4 describes an invention that aims to provide a holding device that can control the temperature of an object with high accuracy while reducing the occurrence of abnormal discharge. Specifically, it describes a holding device comprising a ceramic substrate having a first surface that holds an object and a second surface located on the opposite side of the first surface; a base member disposed on the second surface side of the ceramic substrate, the base member having a third surface located on the opposite side of the ceramic substrate; and a bonding material disposed between the ceramic substrate and the base member; wherein (1) a passage is formed in the ceramic substrate and the base member to allow fluid to communicate between an outflow hole provided on the first surface and an inflow hole provided on the third surface, or (2) a passage is formed in the ceramic substrate to enable fluid to communicate between an outflow hole provided on the first surface and an inflow hole provided on the second surface; wherein the passage is provided with a porous ceramic region; and wherein the porous ceramic region comprises a sparse region and a dense region having a lower porosity than the sparse region and disposed closer to the first surface than the sparse region. According to Patent Literature 4, it is described that a porous ceramic region can be formed by producing a cylindrical porous body M having various porosities in the axial direction and fitting it into a large diameter portion provided at a predetermined connection portion in the manufacturing process of a ceramic substrate.

Patent Literature 5 discloses a wafer placement table in which an insulating first porous portion disposed within the through hole of the ceramic plate, and an insulating second porous portion fitted into a recess provided on the ceramic plate side of the base plate so as to face the first porous portion are provided. The gas supplied to the gas introduction path passes through the second porous portion and the first porous portion, flows into the space between the wafer placement surface and the wafer, and is used to cool the object. It is described that due to the presence of the first porous portion and the second porous portion, it is possible to suppress the occurrence of electrical discharge (arc discharge) caused by plasma upon processing wafers while ensuring the gas flow rate from the gas introduction passage to the wafer placement surface. According to Patent Literature 5, when both the first porous portion and the ceramic dielectric substrate are sintered and integrated, the strength of the electrostatic chuck can be improved compared to cases in which adhesive is used therebetween. It is also described that the electrostatic chuck does not deteriorate due to corrosion or erosion of the adhesive.

### PRIOR ART

### Patent Literature

[Patent Literature 1] Japanese Patent Application Publication No. 2022-119338

[Patent Literature 2] Japanese Patent Application Publication No. 2022-31333

[Patent Literature 3] Japanese Patent Application Publication No. 2019-165194

[Patent Literature 4] Japanese Patent Application Publication No. 2022-176701

[Patent Literature 5] Japanese Patent Application Publication No. 2020-72262

### SUMMARY OF THE INVENTION

As described above, various techniques have been proposed for semiconductor manufacturing equipment members to improve the structure in the vicinity of plugs disposed in gas passage portions that vertically penetrate a ceramic substrate in order to suppress the electrical discharge that occurs between the wafer and the base plate. Further, it is also known that deterioration due to corrosion, erosion, or the like of the adhesive can be prevented by not using an adhesive when fixing the plug to the gas passage section. However, if no adhesive is used, the fixing strength of the plug tends to decrease, and there is a problem in that the accuracy of positioning the plug in the height direction when embedding the plug in the plug placement hole decreases. Therefore, there is still room for improvement in the technology for embedding a plug in a plug placement hole with high positioning accuracy without using adhesives.

In view of the above circumstances, an object of an embodiment of the present invention is to provide a member for a semiconductor manufacturing equipment that allows a plug to be embedded in a plug placement hole with high positioning accuracy without using adhesives.

The present inventor has made extensive studies to solve the above problems, and has created the present invention as exemplified below.

### Aspect 1

A member for a semiconductor manufacturing equipment, comprising:
a ceramic substrate having an upper surface on which a wafer is to be placed and a lower surface;
a plug placement hole that vertically penetrates the ceramic substrate and comprises a tapered inner peripheral surface in which an area of an upper opening is larger than an area of a lower opening;
a ceramic plug comprising a dense outer peripheral surface and a gas passage penetrating the plug, the ceramic plug being embedded such that the dense outer peripheral surface of the plug is directly fitted to the inner peripheral surface of the plug placement hole;
a conductive base plate bonded to the lower surface of the ceramic substrate via a bonding layer; and
a gas supply path that passes through the base plate and the bonding layer to supply gas to the gas passage of the ceramic plug.

### Aspect 2

The member for a semiconductor manufacturing equipment according to claim 1, wherein the inner peripheral surface of the plug placement hole has an inclination angle of 70° or more and 87° or less with respect to the lower opening.

### Aspect 3

The member for a semiconductor manufacturing equipment according to claim 1 or 2, wherein the inner peripheral surface of the plug placement hole is fitted to the dense outer peripheral surface of the ceramic plug is dense.

### Aspect 4

The member for a semiconductor manufacturing equipment according to any one of aspects 1 to 3, wherein a material constituting the ceramic plug and a material constituting the ceramic substrate both comprise one or more selected from aluminum oxide and aluminum nitride.

### Aspect 5

The member for a semiconductor manufacturing equipment according to any one of aspects 1 to 4, wherein a porosity of the dense outer peripheral surface of the ceramic plug is 1% or less.

### Aspect 6

The member for a semiconductor manufacturing equipment according to any one of aspects 1 to 5, wherein the ceramic plug has a truncated conical outer shape.

### Aspect 7

The member for a semiconductor manufacturing equipment according to any one of aspects 1 to 6, wherein a thickness from the upper opening to the lower opening of the ceramic substrate is 1 mm or more.

### Aspect 8

The member for a semiconductor manufacturing equipment according to any one of aspects 1 to 7, wherein when the ceramic plug is punched out of the plug placement hole in a direction from the lower opening toward the upper opening of the plug placement hole according to a punching test method described in the detailed specification, a punching strength is 1 N/mm² or more.

A member for a semiconductor manufacturing equipment according to an embodiment of the present invention comprises a plug placement hole having a tapered inner peripheral surface in which the area of the upper opening is larger than the area of the lower opening. Since this plug placement hole serves as a stopper, the plug can be easily stopped at a predetermined height position of the plug placement hole when the plug is embedded in the plug placement hole. In other words, the member for a semiconductor manufacturing equipment has the effect that the plug can be embedded in the plug placement hole with high positioning accuracy. Further, since the plug placement hole has such a structure, it becomes difficult for the plug to come out downward, but it becomes relatively easy to come out upwards. This also makes it easier to replace the plug. Furthermore, since the creepage distance becomes longer, an effect of suppressing discharge can also be obtained.

In addition, by appropriately setting the inclination angle of the inner peripheral surface of the plug placement hole and using a plug that has an outer peripheral surface that can fit into the plug placement hole, it is possible to prevent the plug from coming off too easily upwards.

### BRIEF DESCRIPTION OF THE DRAWINGS

FIG. 1 is a schematic vertical cross-sectional view of a member for a semiconductor manufacturing equipment according to an embodiment of the present invention.

FIG. 2 is a partially enlarged view of FIG. 1.

FIG. 3 is a schematic plan view of a ceramic substrate according to one embodiment.

FIG. 4 is a schematic vertical cross-sectional view of a member for a semiconductor manufacturing equipment according to another embodiment of the present invention.

FIG. 5 is a schematic vertical cross-sectional view of a compression testing machine used in a punching test.

FIGS. 6A-6C are manufacturing process diagrams of a member for a semiconductor manufacturing equipment according to an embodiment of the present invention.

### DETAILED DESCRIPTION OF THE INVENTION

Hereinafter, embodiments of the present invention will now be

described in detail with reference to the drawings. It should be understood that the present invention is not intended to be limited to the following embodiments, and any change, improvement or the like of the design may be appropriately added based on ordinary knowledge of those skilled in the art without departing from the spirit of the present invention. In addition, as used herein, “upper” and “lower” are used to conveniently express the relative positional relationship when a member for a semiconductor manufacturing equipment is placed on a horizontal plane with a base plate facing downward, and they do not represent any absolute positional relationships. Therefore, depending on the orientation of the member for a semiconductor manufacturing equipment, “upper” and “lower” may become “lower” and “upper”, or “left” and “right”, or “front” and “rear”.

### 1. Configuration of Member for Semiconductor Manufacturing Equipment

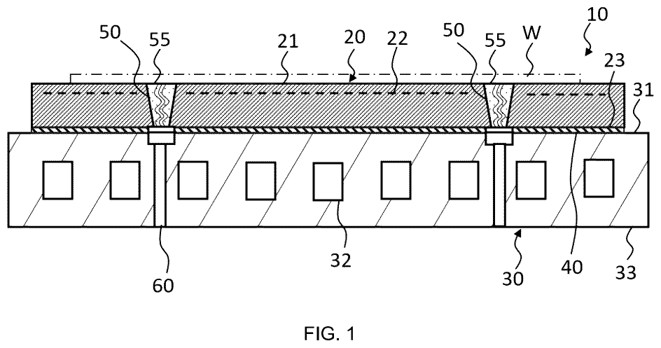

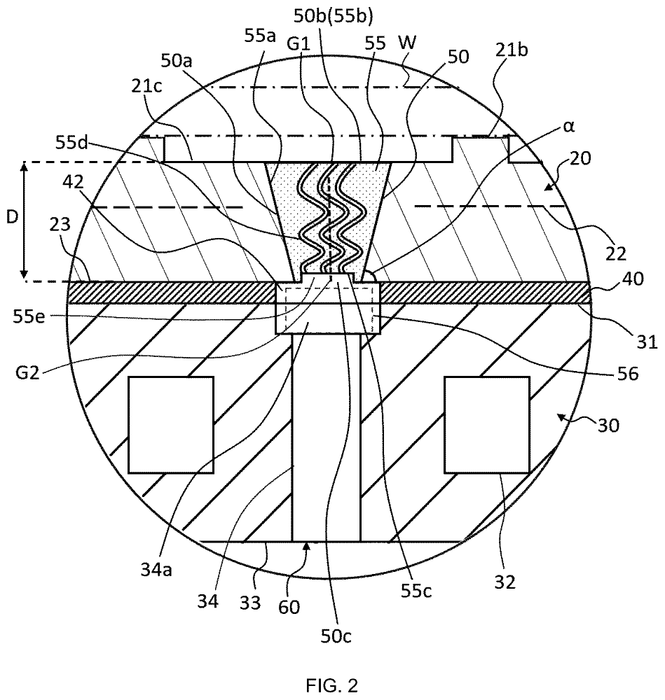

Referring to FIGS. 1 and 2, a member 10 for a semiconductor manufacturing equipment according to an embodiment of the present invention comprises:
a ceramic substrate 20 having an upper surface 21 on which a wafer is to be placed and a lower surface 23 opposite to the upper surface 21;
a plug placement hole 50 that vertically penetrates the ceramic substrate 20 and comprises a tapered inner peripheral surface 50a in which an area of an upper opening 50b is larger than an area of a lower opening 50c;
a ceramic plug 55 comprising a dense outer peripheral surface and a gas passage penetrating the plug, the ceramic plug 55 being embedded such that the dense outer peripheral surface 55a of the plug 55 is directly fitted to the inner peripheral surface 50a of the plug placement hole 50;
a conductive base plate 30 bonded to the lower surface 23 of the ceramic substrate 20 via a bonding layer 40; and
a gas supply path 60 that passes through the base plate 30 and the bonding layer 40 to supply gas to the gas passage 55d of the ceramic plug 55.

The ceramic substrate 20 can be, for example, a circular plate (for example, 300 to 400 mm in diameter) made of ceramics such as alumina sintered body or aluminum nitride sintered body. Although the thickness of the ceramic substrate 20 is not limited, from the viewpoint of increasing the fixing strength of the plug 55, it is preferable that the thickness from an upper opening 50b to a lower opening 50c be 1 mm or more. Further, from the viewpoint of reducing heat transfer of the ceramic substrate 20 and reducing manufacturing costs, the thickness is preferably 5 mm or less, more preferably 3 mm or less, and even more preferably 2 mm or less, for example. Therefore, the thickness from the upper opening 50b to the lower opening 50c is preferably 1 to 5 mm, more preferably 1 to 3 mm, and even more preferably 1 to 2 mm. Here, the thickness from the upper opening 50b to the lower opening 50c means the distance D1 from the center of gravity G1 of the upper opening 50b to the center of gravity G2 of the lower opening 50c. The height of the upper opening 50b is equal to the height of the reference surface 21c of the upper surface 21 of the ceramic substrate 20. The height of the lower opening 50c is equal to the height of the lower surface 23 of the ceramic substrate 20.

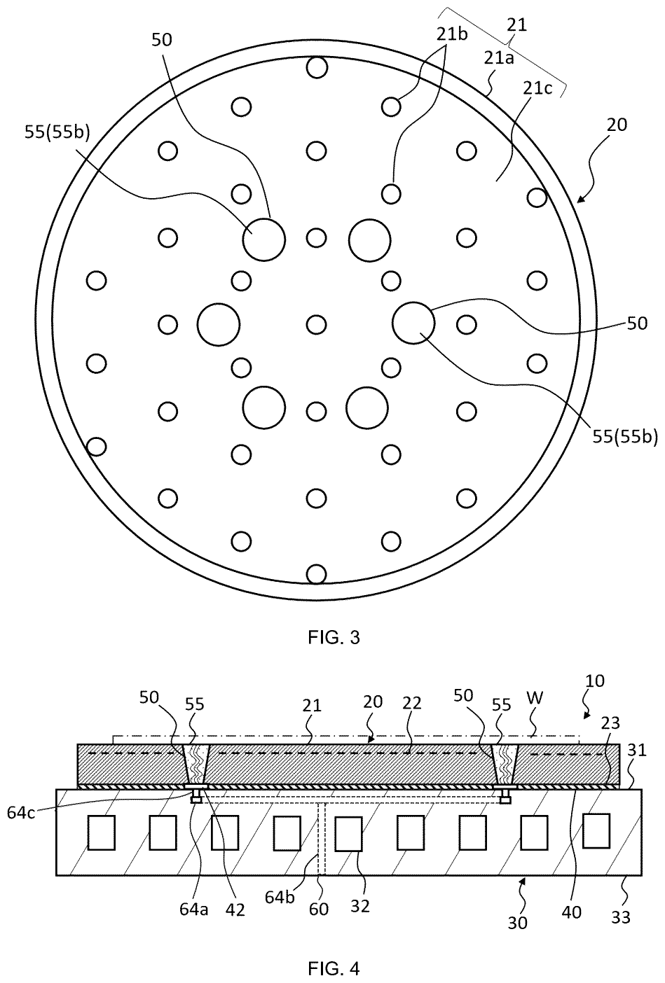

The upper surface 21 of the ceramic substrate 20 has a wafer placement surface on which the wafer W is to be placed. An electrode 22 is provided inside the ceramic substrate 20. As shown in FIG. 3, on the upper surface 21 of the ceramic substrate 20, an annular seal band 21a is formed along the outer edge, and a plurality of small protrusions 21b are formed on the entire surface inside the seal band 21a. Although the shape of the small protrusion 21b is not limited, it can be, for example, a cylinder, a prism, or the like. It is preferable that the seal band 21a and the small protrusions 21b have the same height, and the height is, for example, 5 to 100 μm, and typically 10 to 30 μm. The electrode 22 is a planar electrode used as an electrostatic electrode, and is connected to an external DC power source via a power supply member (not shown). A low-pass filter may be placed in the middle of the power supply member. The power supply member is electrically insulated from the bonding layer 40 and the base plate 30. When a DC voltage is applied to this electrode 22, the wafer W is adsorbed and fixed to the wafer placement surface (specifically, the upper surface of the seal band 21a and the upper surface of the small protrusion 21b) by electrostatic attraction force, and when the application of the DC voltage is released, the adsorption and fixation of the wafer W to the wafer placement surface is released. In addition, the portion of the upper surface 21 of the ceramic substrate 20 where the seal band 21a and the small projections 21b are not provided is referred to as the reference surface 21c.

As the electrode 22, a heater electrode (resistance heating element) may be incorporated instead of or in addition to the electrostatic electrode. In that case, a heater power source is connected to the heater electrode. One layer of electrode may be provided inside the dielectric substrate 20, or two or more layers which are spaced apart from each other may be provided inside the dielectric substrate 20.

The conductive base plate 30 is a circular plate (having a diameter equal to or larger than that of the ceramic substrate 20) with good electrical conductivity and thermal conductivity. Inside the base plate 30, a refrigerant passage 32 through which refrigerant circulates may be formed. The refrigerant flowing through the refrigerant passage 32 is preferably liquid and preferably electrically insulating. Examples of the electrically insulating liquid include fluorine-based inert liquids. The refrigerant passage 32 can be formed, for example, in a single stroke across the entire base plate 30 from one end (inlet) to the other end (outlet) in a plan view. A supply port and a recovery port of an external refrigerant device (not shown) are connected to the one end and the other end of the refrigerant passage 32, respectively. The refrigerant supplied from the supply port of the external refrigerant device to the one end of the refrigerant passage 32 passes through the refrigerant passage 32 and then returns from the other end of the refrigerant passage 32 to a recovery port of the external refrigerant device, and after the temperature has been adjusted, the refrigerant is again supplied to the one end of the refrigerant passage 32 from the supply port. The base plate 30 is connected to a radio frequency (RF) power source and can also be used as an RF electrode.

Examples of the material of the base plate 30 include metal materials and composite materials of metal and ceramics. Examples of the metal material include Al, Ti, Mo, W, and alloys thereof. Examples of composite materials of metal and ceramics include metal matrix composites (MMC) and ceramic matrix composites (CMC). Specific examples of such composite materials include materials containing Si, SiC, and Ti (also referred to as SiSiCTi), materials in which porous SiC is impregnated with Al and/or Si, and composite materials of Al₂O₃ and TiC. A material in which a porous SiC body is impregnated with Al is called AlSiC, and a material in which a porous SiC body is impregnated with Si is called SiSiC. It is preferable to select a material for the base plate 30 that has a coefficient of thermal expansion close to that of the material for the ceramic substrate 20. For example, when the ceramic substrate 20 is made of alumina, the base plate is preferably made of SiSiCTi or AlSiC.

As shown in FIG. 2, the upper surface 31 of the base plate 30 is bonded to the lower surface 23 of the ceramic substrate 20 via a bonding layer 40. The bonding layer 40 is formed by, for example, TCB (thermal compression bonding). TCB is a known method in which a metal bonding material is sandwiched between two members to be bonded, and the two members are pressure bonded while being heated to a temperature below the solidus temperature of the metal bonding material. The bonding layer 40 can be composed of a metal bonding layer using, for example, an Al—Mg-based bonding material or an Al—Si—Mg-based bonding material. The bonding layer 40 may be a layer formed of solder or a metal brazing material. Furthermore, the bonding layer 40 may be composed of a resin adhesive layer instead of the metal bonding layer. Examples of the material for the resin adhesive layer include silicone resin-based adhesives, epoxy resin-based adhesives, and acrylic resin-based adhesives. In order to improve the uniformity of the thickness of the resin adhesive layer, a spacer (not shown) may be placed between the upper surface 31 of the base plate 30 and the lower surface 23 of the ceramic substrate 20.

The bonding layer 40 has a through hole 42. The through hole 42 is provided at a position facing a large diameter portion 34a of a gas hole 34. The through hole 42 may be provided coaxially with the large diameter portion 34a, and the diameter of the through hole 42 may be made to match the diameter of the large diameter portion 34a. As used herein, “match” includes not only a complete match but also a substantially match (for example, within a tolerance range) (the same applies hereinafter). In the present embodiment, the gas hole 34 and the through hole 42 correspond to the gas supply path 60 that passes through the base plate 30 and the bonding layer 40 to supply gas to the plug 55.

The plug placement hole 50 is a hole that vertically penetrates the ceramic substrate 20, as shown in FIGS. 1 and 2. The plug placement hole 50 is a gas passage from the lower surface 23 of the ceramic substrate 20 to the reference surface 21c of the upper surface 21. The opening diameter (if the cross section of the plug placement hole is not circular, it means the equivalent circle diameter.) of the plug placement hole 50 in the horizontal direction is not limited, but may be within the range of 1 to 5 mm, typically within the range of 3 to 4 mm, at any height position. The diameter of the plug placement hole 50 decrease from top to bottom, and it has a tapered inner peripheral surface 50a in which the area of the upper opening 50b is larger than the area of the lower opening 50c. Since the plug placement hole 50 has such a tapered inner peripheral surface 50a, when embedding the plug 55 into the plug placement hole 50, the plug 55 can easily stop at a predetermined height position of the plug placement hole 50. Therefore, it is possible to obtain an effect that the plug can be embedded in the plug placement hole with high positioning accuracy. Further, while the plug becomes difficult to come out downward, it becomes relatively easy to come out upward, so that the effect of making it easy to replace the plug can be obtained. Furthermore, since the creepage distance becomes longer, an effect of suppressing discharge can also be obtained. The plug placement hole 50 can have, for example, a truncated conical or truncated pyramid space.

The inclination angle a of the inner peripheral surface 50a of the plug placement hole 50 with respect to the lower opening 50c is preferably 70° or more, and preferably 75° or more, from the viewpoint of increasing the fixing strength of the plug 55, and from the viewpoint of suppressing the volume of the plug 55 from becoming excessively large and securing space for arranging the electrode around it. In addition, it is preferable that the inclination angle α be 87° or less, and more preferable that it is 85° or less, from the viewpoint of improving the positioning accuracy in the height direction of the plug when press-fitting the plug 55 downward into the plug placement hole 50, from the viewpoint of making it easy to replace the plug 55, and from the viewpoint of increasing the creepage distance to prevent discharge. Therefore, the inclination angle a is preferably, for example, 70° to 87°, and more preferably 75° to 85°.

As shown in FIG. 3, in the member for a semiconductor manufacturing equipment according to the present embodiment, a plurality of (six in this case) plug placement holes 50 are provided. A ceramic plug 55 is embedded in the plug placement hole 50. The ceramic plug 55 has a gas passage 55d that penetrates the inside of the ceramic plug 55. In one embodiment, the gas passage 55d has one opening on the lower surface 55c of the plug 55 and the other opening on the upper surface 55b, and penetrates the inside of the plug 55 in the vertical direction. In another embodiment, the gas passage 55d has one opening in the lower surface 55c of the plug 55 and the other opening in the outer peripheral surface 55a, and penetrates the inside of the plug 55. The outer peripheral surface 55a of the ceramic plug 55 and the inner peripheral surface 50a of the plug placement hole 50 are directly fitted together without using an adhesive. Since the two are directly fitted, no gap will be created between the ceramic plug 55 and the plug placement hole 50 caused by deterioration due to corrosion or erosion of the adhesive. Therefore, there is an advantage that discharge and falling off of the ceramic plug 55 due to deterioration of the adhesive can be suppressed. Further, the natural frequency of the ceramic substrate 20 in which the plug 55 is embedded in the plug placement hole 50 may be 1000 KHz or more. In this case, since the natural frequency is on the high frequency side, there is an advantage that the plug can be prevented from falling off due to vibrations such as transport vibrations, which are on the low frequency side.

As shown in FIGS. 1 and 2, when observing a longitudinal cross section obtained by cutting the ceramic substrate 20 in the thickness direction, it is preferable that the inner peripheral surface 50a of the plug placement hole 50 be in contact with the outer peripheral surface 55a of the ceramic plug 55 in a parallel positional relationship, from the viewpoint of improving the fixing strength of the ceramic plug 55. In other words, the outer peripheral surface 55a of the ceramic plug 55 has the same inclination angle as the inner peripheral surface 50a of the plug placement hole 50. Therefore, in a preferred embodiment, the ceramic plug has an outer shape that is the same as the plug placement hole (for example, a truncated cone or a truncated pyramid). Thereby, the area in which the inner peripheral surface 50a of the plug placement hole 50 contacts the outer peripheral surface 55a of the ceramic plug 55 can be increased, and high fixing strength can be obtained.

An example of a direct fitting method is a method of embedding the ceramic plug 55 by press-fitting it into the plug placement hole 50. In this case, in order to obtain the desired fixation strength, it is preferable that the cross-sectional diameter in the horizontal direction at any height position of the ceramic plug 55 before press-fitting is made slightly larger (for example, by about 5 to 20 μm in equivalent circle diameter) than the horizontal cross-sectional diameter of the plug placement hole 50 located at the same height position. Further, as a direct fitting method, there is also a method in which a male threaded portion provided on the outer peripheral surface 55a of the ceramic plug 55 is screwed into a female threaded portion provided on the inner peripheral surface 50a of the plug placement hole 50. Furthermore, the ceramic plug 55 may be formed by injecting a paste-like ceramic mixture that is a precursor of the ceramic plug 55 into the plug placement hole 50 of the ceramic substrate 20 and firing it.

Preferably, the ceramic plug 55 has a dense outer peripheral surface 55a. If the ceramic plug 55 has a dense outer peripheral surface 55a, when the ceramic plug 55 is directly fitted to the inner peripheral surface 50a of the plug placement hole 50, a sufficient frictional force acts, thereby increasing the fixing strength of the ceramic plug 55. The fact that the outer peripheral surface 55a is dense means that the porosity of the outer peripheral surface 55a is 5% or less. The porosity of the outer peripheral surface 55a is preferably 1% or less, more preferably 0.5% or less.

The porosity of the outer peripheral surface 55a is measured by the following method. The ceramic plug 55 is cut such that a cross section perpendicular to the outer peripheral surface 55a of the ceramic plug 55 is exposed. Next, a 100 μm thick portion of the cross section from the outer peripheral surface 55a is observed using a scanning electron microscope (SEM) at a magnification of 3000 times in approximately 2200 μm², and the area ratio of pores confirmed in the relevant thickness portion is calculated. Specifically, by analyzing the SEM image, a threshold value is determined from the luminance distribution of luminance data of pixels in the image using a discriminant analysis method (Otsu's binarization). Thereafter, each pixel in the image is binarized into solid portions and pore portions based on the determined threshold value, and the area of the solid portions and the area of the pore portions are calculated. Then, the ratio of the area of the pore portions to the total area (total area of the solid portions and the pore portions) is determined. The same measurements are performed at five locations on the same ceramic plug 55, and the average value of the measurements at five locations is taken as the porosity of the outer peripheral surface 55a of the ceramic plug 55.

Further, when the outer peripheral surface 55a of the ceramic plug 55 and the inner peripheral surface 50a of the plug placement hole 50 are directly fitted, it is preferable that the inner peripheral surface 50a of the plug placement hole 50 be also dense, from the viewpoint of increasing the fixing strength of the ceramic plug 55 due to friction. The fact that the inner peripheral surface 50a is dense means that the porosity of the inner peripheral surface 50a is 5% or less. Therefore, the porosity of the inner peripheral surface 50a is preferably 1% or less, more preferably 0.5% or less.

Since the inner peripheral surface 50a is a part of the ceramic substrate 20, as used herein, the value of the porosity of the ceramic substrate 20 is regarded as the porosity of the inner peripheral surface 50a. The porosity of the ceramic substrate 20 is defined as the open porosity measured according to JIS R1634: 1998, and the measured value is the average value of the open porosity for five samples uniformly taken from the ceramic substrate 20.

The height position of the upper surface 55b of the ceramic plug 55 is not limited. Therefore, it may be set at the same height as the reference surface 21c of the ceramic substrate 20, or may be set at a different height. However, it is preferable that the height position of the upper surface 55b of the ceramic plug 55 be the same as the reference surface 21c. When the upper surface 55b of the ceramic plug 55 is lower than the reference surface 21c, it is preferable to arrange it at a lower position within a range of 0.5 mm or less (preferably 0.2 mm or less, and more preferably 0.1 mm or less) in order to suppress the occurrence of discharge. When the upper surface of the ceramic plug 55 is made higher than the reference surface 21c, there is no particular restriction as long as it is made lower than the upper surface of the small protrusion 21b and the outflow of the gas from the ceramic plug 55 is not inhibited.

There is no particular restriction on the height position of the lower surface 55c of the ceramic plug 55. Therefore, it may be at the same height as the lower surface 23 of the ceramic substrate 20, or may be at a different height. For example, the lower surface 55c of the ceramic plug 55 may protrude below the lower surface 23 of the ceramic substrate 20, or the lower surface 55c of the ceramic plug 55 may be located above the lower surface 23 of the ceramic substrate 20. However, for gas to be introduced from the lower surface 23 of the plug 55, it is preferable to provide a gas introduction space between the lower surface 55c of the ceramic plug 55 and the bonding layer 40. The gas introduction space can be formed, for example, by a recess 55e provided in the lower surface 55c of the ceramic plug 55.

As the materials constituting the ceramic plug 55, ceramics can be used, and for example, it may contain one or more selected from aluminum oxide, aluminum nitride, quartz, zirconia, and the like. It can also be composed of one or two selected from aluminum oxide and aluminum nitride, excluding impurities. For example, a plurality of plugs made of different materials may be stacked in the vertical direction. In this case, if the upper plug is made of ceramic with a higher volume resistivity than the lower plug, by bringing the lower plug into contact with the base plate or electrical conductor, the potential of the lower plug can be lowered, and it is possible to aim for the effect of suppressing discharge in the lower portion, where the space is wider and discharge is more likely to occur. Specifically, the upper plug may be made of aluminum oxide, the lower plug may be made of SiC, and they may be placed in order in the plug placement hole.

From the viewpoint of maintaining the fixing strength of the ceramic plug 55, it is preferable that the difference in thermal expansion coefficient between the ceramic plug 55 and the ceramic substrate 20 be small. Therefore, it is preferable that the material constituting the ceramic plug 55 and the material constituting the ceramic substrate 20 both contain one or more selected from aluminum oxide and aluminum nitride, and it is more preferable that the material compositions are the same.

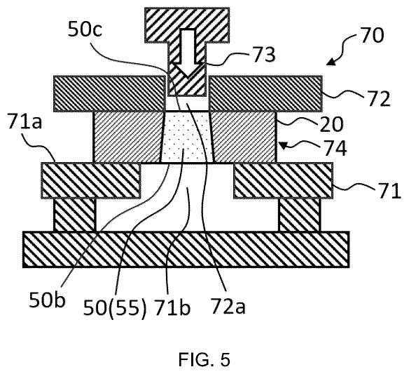

As used herein, the fixing strength of the ceramic plug 55 is measured according to the following punching test method. FIG. 5 shows a schematic vertical cross-sectional view of a compression testing machine 70 used in the punching test. The compression testing machine 70 includes a pedestal 71, a cover plate 72, and a punching pin 73 (cylindrical with a tip diameter of 3 mm) that can move up and down at a predetermined speed. The pedestal 71 has a placement surface 71a for a test piece 74, and a through hole 71b for dropping the ceramic plug 55 punched out of the test piece 74. The cover plate 72 has an insertion hole 72a through which the punching pin 73 is inserted in the vertical direction. The material of the pedestal 71 is metal. The material of the cover plate 72 is metal. The punching pin 73 is made of metal.

Next, the punching test method will be explained. First, a test piece 74 of the ceramic substrate 20 in which the ceramic plug 55 is embedded in the plug placement hole 50 is placed on the placement surface 71a of the pedestal 71 such that the lower opening 50c of the plug placement hole 50 is on the upper side and the upper opening 50b is on the lower side, and then it is fixed by sandwiching it with the cover plate 72 from above. Further, the through hole 71b of the pedestal 71, the plug placement hole 50 of the test piece 74, and the insertion hole 72a of the cover plate 72 are arranged coaxially. Next, the punching pin 73 is moved downward from the top of the cover plate 72 at a speed of 1 mm/min, and the ceramic plug 55 is punched out of the test piece 74 in a direction from the lower opening 50c of the plug placement hole 50 toward the upper opening 50b. The load when punching the test piece 74 is continuously measured, and the measured maximum pressure is defined as the punching strength. As used herein, this punching strength is regarded as the fixing strength of the ceramic plug 55.

In one embodiment of the invention, the punching strength is greater than or equal to 1 N/mm². The punching strength is preferably 5 N/mm² or more, and more preferably 20 N/mm² or more. There is no particular limit to the upper limit of the punching strength, but from the viewpoint of making the plug easy to pull out without damaging the ceramic plate when replacing the plug, it is, for example, 300 N/mm² or less, more preferably 100 N/mm² or less, and even more preferably 50 N/mm² or less. Therefore, the punching strength is preferably, for example, 1 to 300 N/mm², more preferably 5 to 100 N/mm², and even more preferably 20 to 50 N/mm².

The ceramic plug 55 has a gas passage 55d penetrating the inside of the plug 55. In one embodiment, the gas passage 55d has a structure in which gas flows in from the lower surface 55c of the ceramic plug 55, flows through the gas passage 55d, and flows out from the upper surface 55b of the ceramic plug 55. For example, the gas passage 55d may be formed by forming one or more gas passages penetrating in the vertical direction in a dense material that does not allow the gas to flow. In this case, the gas flowing in from the lower surface 55c of the ceramic plug 55 flows through the gas passage and flows out from the upper surface 55b of the ceramic plug 55. The gas passage may be constructed of a straight line, a curved line, or a combination of both, but from the viewpoint of suppressing discharge, it is preferable to have a shape such that the length of the passage is longer than the length of the ceramic plug 55 in the vertical direction, for example, a curved shape such as a spiral shape or a zigzag shape. The fact that the ceramic plug 55 is dense means that the porosity of the outer peripheral surface 55a is 5% or less. The porosity of the ceramic plug 55 is preferably 1% or less, more preferably 0.5% or less.

The porosity of the ceramic plug 55 is measured by the following method. The ceramic plug 55 is cut so that a cross section passing through the central axis extending in the vertical direction of the ceramic plug 55 is exposed. Next, a portion of the cross section excluding the gas passage 55d is observed using a scanning electron microscope (SEM) at a magnification of 3000 times in approximately 2200 μm², and the area ratio of pores confirmed in the relevant portion is calculated. Specifically, by analyzing the SEM image, a threshold value is determined from the luminance distribution of luminance data of pixels in the image using a discriminant analysis method (Otsu's binarization). Thereafter, each pixel in the image is binarized into solid portions and pore portions based on the determined threshold value, and the area of the solid portions and the area of the pore portions are calculated. Then, the ratio of the area of the pore portions to the total area (total area of the solid portions and the pore portions) is determined. The same measurements are performed at five locations on the same ceramic plug 55, and the average value of the measurements at five locations is taken as the porosity of the ceramic plug 55.

As a method of manufacturing the ceramic plug 55 having a gas passage in a dense material, mention may be made to a method of firing a formed body formed using additive manufacturing technology such as a 3D printer, and a method of firing a formed body formed by mold casting using a master mold produced by a lost wax method, for example. Mold casting is disclosed in, for example, Japanese Patent No. 7144603.

Further, a porous portion may be provided in the ceramic plug 55 to serve as the gas passage 55d. When the gas passage 55d is porous, the gas flowing in from the lower surface 55c of the plug 55 flows through the gas passage 55d formed by a large number of continuous pores, and flows out from the upper surface 55b of the plug 55. Since three-dimensional (for example, three-dimensional network) continuous pores that exist within the porous material serve as gas passages, the substantial passage length within the gas passage 55d becomes longer compared to the case where the gas passage 55d is hollow, and an effect that electric discharge is less likely to occur can be obtained. The porous gas passage can be formed on the inner peripheral side of the dense outer peripheral surface. It is also possible to further form one or more gas passages within the porous gas passage.

Therefore, the gas passage 55d may be hollow or porous. It is preferable that at least a part of the gas passage 55d is porous. The fact that the gas passage 55d is hollow means that the porosity is 100%. The fact that the gas passage 55d is porous means that the porosity of the gas passage 55d is greater than 5% and less than 100%. The porosity of the gas passage 55d is preferably large in order to reduce ventilation resistance. Therefore, the porosity of the gas passage 55d is preferably 10% or more, and more preferably 40% or more. On the other hand, the porosity of the gas passage 55d is preferably 50% or less in order to lengthen the passage length of the ceramic plug 55 and ensure structural strength. Therefore, the porosity of the gas passage 55d is, for example, preferably 10% or more and 50% or less, and more preferably 40% or more and 50% or less.

The porosity of the gas passage 55d is measured, for example, by mercury porosimetry method (JIS R1655: 2003).

The porosity of the ceramic plug and the ceramic substrate can be controlled, for example, by adjusting the content of the pore-forming material in the raw material composition before producing by firing the ceramics which they are made of. For example, in order to make the outer peripheral surface of the ceramic plug denser, the amount of pore-forming material near the outer peripheral surface may be partially reduced or may not be used. Furthermore, in order to make the inner peripheral surface of the plug placement hole denser, the amount of pore-forming material near the inner peripheral surface may be partially reduced or may not be used.

Referring to FIG. 2, the gas supply path 60 for supplying gas to the gas passage 55d of the ceramic plug 55 through the base plate 30 and the bonding layer 40 has, for example, a through hole 42 that vertically penetrates the bonding layer 40 and a gas hole 34 that communicates with the through hole 42 and penetrates the base plate 30 from the upper surface 31 to the lower surface 33. In the present embodiment, the upper surface 31 of the base plate 30 may further comprise a large diameter portion 34 a provided at a position facing the through hole 42. By having the through hole 42 and furthermore the large diameter portion 34a, when placing the ceramic plug 55 in the plug placement hole 50, even if there is a manufacturing error in the plug placement hole 50 and/or the ceramic plug 55, such a manufacturing error can be absorbed because a space is created that allows the ceramic plug 55 to enter. Alternatively, the gas hole 34 may be a straight hole with a diameter larger than the diameter of the lower opening of the plug placement hole 50.

Further, an electrical conductor 56 may be provided in one or both of the through hole 42 and the large diameter portion 34a. By providing the electric conductor 56, discharge can be further suppressed. The electrical conductor 56 only needs to be configured such that the flow of gas through the gas supply path 60 is not blocked, and the gas does not need to be able to pass through the interior of the electrical conductor 56. Furthermore, the electrical conductor 56 may have a structure through which gas can pass. In this case, the gas in the gas supply path 60 can pass through the interior of the electrical conductor 56 and flow into the plug placement hole 50. Examples of the member through which gas can pass include a conductive mesh, a massive body of conductive fibers, a conductive porous body, and a conductive elastic body.

Examples of the material constituting the electrical conductor 56 include inorganic materials such as metal, carbon, and conductive ceramics. Accordingly, in one embodiment, electrical conductor 56 contains metal, carbon, conductive ceramics, or a composite material of two or more thereof.

Composite materials of metal and ceramics may also be mentioned. Examples of metals include single metals selected from Au, Ag, Al, Ti, and Mo or alloys containing one or more of these, stainless steels such as SUS316L, highly corrosion-resistant Ni alloys such as Hastelloy, and steel, and the like. Examples of carbon include diamond-like carbon (DLC). Further, the surface of the inorganic material may be coated with diamond-like carbon (DLC). Examples of conductive ceramics include SiC and SiSiC.

When the electrical conductor 56 is a conductive mesh, the opening may be 0.062 mm (250 mesh) to 0.154 mm (100 mesh). When the electric conductor 56 is a massive body of conductive fibers, examples thereof include steel wool, carbon felt, porous metal made by sintering Ti fibers and Al powder.

It is preferable that the electric conductor 56 is made of a member having elasticity such as a porous body or an elastic body. Preferably, the electrical conductor 56 contacts both the plug 55 and the base plate 30. In that case, it is desirable that at least a portion of the lower surface 55c of the plug 55 be covered with a conductive film, and that the film be in contact with the electrical conductor 56. Examples of the material constituting the conductive film include metal, carbon, and conductive ceramics. Composite materials of metal and ceramics may also be mentioned. When the material of the porous body is fibrous or porous, such as Ti or SUS, the effect of suppressing discharge can be enhanced while suppressing an increase in ventilation resistance. Further, by being porous or elastic, contact with the plug 55 and the base plate 30 can be easily maintained. By porous it is meant that the electrical conductor 56 has a porosity greater than 5%. The electrical conductor 56 preferably has a large porosity in order to reduce ventilation resistance. More preferably, the electrical conductor 56 has a porosity of 40% or more. On the other hand, the porosity of the electrical conductor 56 is preferably 50% or less in order to improve the discharge suppressing effect. Therefore, the porosity of the electric conductor 56 is preferably, for example, more than 5% and 50% or less, more preferably 40% or more and 50% or less.

The porosity of the electrical conductor 56 is measured, for example, by mercury porosimetry method (JIS R1655: 2003).

There are no particular restrictions on the configuration of the gas supply path 60. For example, like a member 10 for a semiconductor manufacturing equipment according to another embodiment of the present invention shown in FIG. 4, the base plate 30 may be provided with one or more ring portions 64a having a passage extending concentrically with the base plate 30 in a plan view, one or more gas introduction portions 64b that supply the gas introduced from the lower surface 33 of the base plate 30 to the ring portions 64a, and a distribution portion 64c that distributes the gas from the ring portions 64a to each plug 55. In the present embodiment, the upper end of the distribution portion 64c communicates with the through hole 42 of the bonding layer 40. In FIG. 4, the same components as those in the embodiment shown in FIG. 1 are given the same reference numerals. The number of gas introduction portions 64b may be smaller than the number of distribution portions 64c, and may be one, for example. In this way, the number of gas pipes connected to the base plate 30 can be made smaller than the number of plugs 55. Other auxiliary passages not shown may also be provided.

Further, a lift pin hole may be provided that penetrates the member 10 for a semiconductor manufacturing equipment. The lift pin hole is a hole through which a lift pin for moving the wafer W up and down with respect to the upper surface 21 of the ceramic substrate 20 is inserted. Lift pin holes are provided, for example, at three locations when the wafer W is supported by three lift pins.

### 2. How to Use a Member for Semiconductor Manufacturing Equipment

Next, a method of using the member 10 for a semiconductor manufacturing equipment configured in this way will be exemplified. First, a wafer W is placed on the upper surface 21 of the ceramic substrate 20 with the member 10 for a semiconductor manufacturing equipment installed in a chamber (not shown). Then, the pressure inside the chamber is reduced with a vacuum pump and adjusted to the desired degree of vacuum, and a voltage is applied to the electrodes 22 of the ceramic substrate 20 to generate electrostatic adsorption force, and the wafer W is adsorbed and fixed to the wafer placement surface (specifically, the upper surface of the seal band 21a or the upper surface of the small protrusion 21b).

Next, the inside of the chamber is set to a reaction gas atmosphere at a predetermined pressure (for example, several tens to several hundreds of Pa), and in this state, a high frequency voltage such as an RF voltage is applied between an upper electrode (not shown) provided on the ceiling of the chamber and the base plate 30 of the member 10 for a semiconductor manufacturing equipment to generate plasma. The surface of the wafer W is processed by the generated plasma. A refrigerant circulates in the refrigerant passage 32 of the base plate 30. Backside gas is introduced into the gas supply path 60 from a gas cylinder (not shown). A thermally conductive gas (for example, He gas) can be used as the backside gas. The backside gas is supplied to the plurality of the plug placement holes 50 through the gas supply path 60, and is supplied and sealed in the space between the back surface of the wafer W and the reference surface 21c of the wafer placement surface. The presence of this backside gas allows efficient heat conduction between the wafer W and the ceramic substrate 20.

Further, by providing the ceramic plug 55 in the plug placement hole 50, electric discharge within the plug placement hole 50 can be suppressed. If there is no ceramic plug 55, electrons generated as gas molecules are ionized by the application of RF voltage are accelerated and collide with other gas molecules, causing glow discharge and eventually arc discharge. However, when the ceramic plug 55 is present, the electrons hit the ceramic plug 55 before colliding with the other gas molecules, so that discharge is suppressed.

### 3. Method for Manufacturing a Member for Semiconductor Manufacturing Equipment

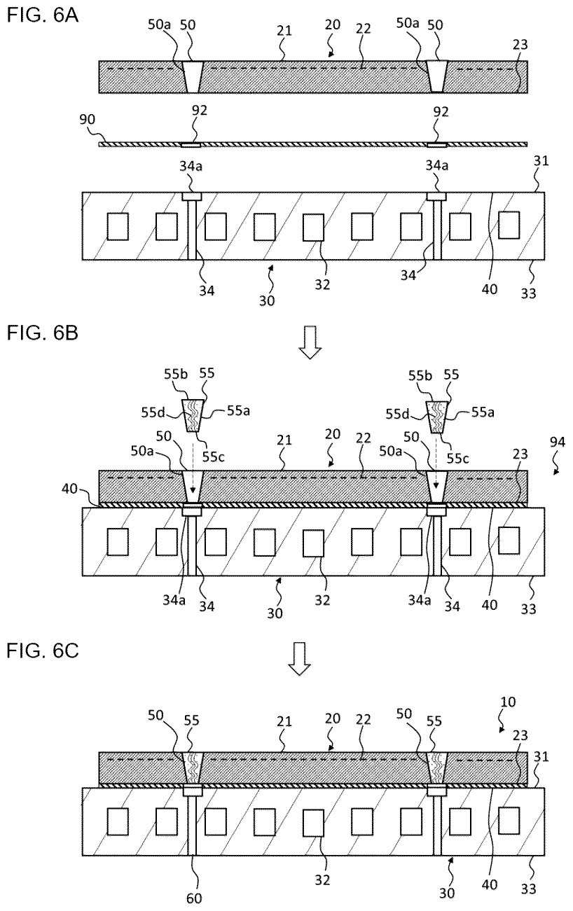

Next, a method for manufacturing the member 10 for a semiconductor manufacturing equipment will be exemplarily described based on FIGS. 6A-6C. FIGS. 6A-6C are manufacturing process diagrams of the member 10 for a semiconductor manufacturing equipment according to an embodiment of the present invention. First, the ceramic substrate 20, the base plate 30, and the metal bonding material 90 are prepared (FIG. 6A).

The ceramic substrate 20 has an electrode 22 therein and a plug placement hole 50. The ceramic substrate 20 can be manufactured by hot press firing a ceramic formed body. The ceramic formed body may be manufactured by laminating a plurality of tape formed bodies, by a mold casting method, or by compacting ceramic powder. Subsequently, the plug placement hole 50 is formed in the ceramic substrate 20. The plug placement hole 50 is formed to vertically penetrate the ceramic substrate 20 while avoiding the electrode 22.

The base plate 30 includes a refrigerant passage 32 and a gas hole 34. The gas hole 34 has a large diameter portion 34a facing the upper surface 31. The base plate 30 including the refrigerant passage 32 can be manufactured, for example, by bonding a plurality of MMC plate members, in which a groove or a hole corresponding to the refrigerant passage 32 is formed, with machining using a method such as TCB (Thermal Compression Bonding). The gas holes 34 can be formed by machining the base plate 30 after the refrigerant passage 32 has been formed.

The metal bonding material 90 includes a through hole 92 at a position facing the large diameter portion 34a of the gas hole 34. The through hole 92 can be formed by machining.

Subsequently, a metal bonding material 90 is sandwiched between the lower surface 23 of the ceramic substrate 20 and the upper surface 31 of the base plate 30 to form a laminate. At this time, they are laminated such that the plug placement hole 50 of the ceramic substrate 20, the through hole 92 of the metal bonding material 90, and the gas hole 34 of the base plate 30 are coaxial. Then, the laminate is pressurized and bonded at a temperature no higher than the solidus temperature of the metal bonding material 90 (for example, the temperature 20° C. lower than the solidus temperature or more and no higher than the solidus temperature), and then returned to room temperature (TCB). Thereby, the metal bonding material 90 and the through hole 92 become the bonding layer 40 and the through hole 42, respectively, and a bonded body 94 in which the ceramic substrate 20 and the base plate 30 are bonded by the bonding layer 40 is obtained (FIG. 6B). The metal bonding material 90 preferably has a thickness of approximately 100 μm (for example, 80 to 240 μm).

Next, a truncated conical ceramic plug 55 having a dense outer peripheral surface 55f, and a gas passage 55d is prepared (FIG. 6B). The height of the ceramic plug 55 is the same as the depth of the plug placement hole 50 (that is, the height of the ceramic substrate 20), which is a truncated conical space. Next, the ceramic plug 55 is press-fitted into the plug placement hole 50 from the upper opening 50b of the ceramic substrate 20 toward the lower opening 50c. Alternatively, a male threaded portion is formed on the outer peripheral surface 55a of the ceramic plug 55, which has been formed in advance by firing or the like, and a female threaded portion is formed on the inner peripheral surface 50a of the plug placement hole 50, and the ceramic plug 55 may be installed by screwing and inserting the ceramic plug 55 into the plug placement hole 50 so that the male threaded portion of the ceramic plug 55 and the female threaded portion of the plug placement hole 50 are screw fitted together. Furthermore, the ceramic plug 55 may be formed by injecting a paste-like ceramic mixture that is a precursor of the ceramic plug 55 into the plug placement hole 50 of the ceramic substrate 20 and firing it. Thereafter, the member 10 for a semiconductor manufacturing equipment is completed by appropriately going through processes such as adjusting the overall shape (FIG. 6C).

### EXAMPLES

### 1. Preparation of Test Piece

### (1-1. Preparation of Ceramic Substrate)

An alumina circular plate with a diameter of 30 mm and a thickness of 5 mm was prepared. In the center of this circular plate, a truncated conical plug placement hole having a tapered inner peripheral surface with an inclination angle with respect to the lower opening listed in Table 1 was formed in accordance with the test number, and a ceramic substrate for testing was thereby obtained.

The porosity of the inner peripheral surface of the plug placement hole was measured in accordance with JIS R1634: 1998 as described above for ceramic substrates separately prepared using the same manufacturing method according to the test number.

### (1-2. Preparation of Ceramic Plug)

An alumina ceramic plug in the shape of a truncated cone with a height of 5 mm and a dense outer peripheral surface was prepared. The ceramic plug was prepared by the following procedure. First, a mold (original mold) for molding the upper and lower surfaces of the plug, the outer peripheral surface, and the hollow gas passage was prepared using a 3D printer. The material used for the mold was a material that is insoluble in ceramics. In addition, it is preferable that the mold be made of a material (for example, paraffin wax) that is soluble in a predetermined cleaning liquid (for example, isopropyl alcohol) after hardening. The portion that will eventually become the plug was hollow. Ceramic slurry was poured into this original mold and fired. Thereafter, it was allowed to cool to room temperature, and the plug was released from the original mold to obtain an alumina ceramic plug.

The inclination angle of the outer peripheral surface of the produced ceramic plug was the same as the inclination angle of the inner peripheral surface of the plug placement hole of the corresponding test number. Further, the horizontal cross-sectional diameter of each plug at any height position was 5 μm larger than the horizontal cross-sectional diameter of the plug placement hole at the same height position.

The porosity of the outer peripheral surface of the ceramic plug was measured by SEM observation as described above for ceramic plugs separately prepared using the same manufacturing method according to the test number.

The porosity of the ceramic plug (whole) was measured by SEM observation as described above for ceramic plugs separately prepared using the same manufacturing method according to the test number.

### (1-3. Press-fitting of Ceramic Plug)

Next, the ceramic plug was press-fitted into the plug placement hole from the upper opening to the lower opening of the ceramic substrate until the upper surface of the ceramic plug was flush with the upper surface of the ceramic substrate. At this time, for all test numbers, the height positions of the upper and lower surfaces of the ceramic plug embedded in the plug placement hole easily matched with the height positions of the upper and lower surfaces of the ceramic substrate, respectively.

### 2. Measurement of Punching Strength

The punching strength of the ceramic plug was measured for the test piece produced in the above procedure according to the punching test method described above. As a compression tester, a universal tester model 5566 manufactured by Instron was used. The compression tester had the configuration shown in FIG. 5, and the test piece was set in the compression tester to measure the punching strength. The results are shown in Table 1.

TABLE 1

| | Plug placement hole | | | Plug | | | |
|---|---|---|---|---|---|---|---|
| | Inner peripheral surface | | | Outer peripheral surface | | Whole | Punching |
| Test | Lower opening | Inclination | Porosity | Inclination | Porosity | Porosity | strength |
| No. | diameter (mm) | angle (°) | (%) | angle (°) | (%) | (%) | (N/mm²) |
| 1 | 2 | 75 | 0 | 75 | 0.5 | 0.5 | 19.7 |
| 2 | 3.5 | 85 | 0 | 85 | 0.5 | 0.5 | 25.5 |

### 3. Discussion

From the test results, it can be understood that in both Examples 1 and 2 of the present invention, it is possible to embed the plug in the plug placement hole with high positioning accuracy without using adhesive. Further, it can be understood that by setting the inclination angle of the inner peripheral surface of the plug placement hole to an appropriate value and using a plug that has an outer peripheral surface that can fit into the plug placement hole, it is possible to prevent the plug from coming out too easily upwards.

### DESCRIPTION OF REFERENCE NUMERALS

10: Member for semiconductor manufacturing equipment
20: Ceramic substrate
21: Upper surface
21a: Seal band
21b: Small protrusion
21c: Reference surface
22: Electrode
23: Lower surface
30: Base plate
31: Upper surface
32: Refrigerant passage
33: Lower surface
34: Gas hole
34a: Large diameter portion
40: Bonding layer
42: Through hole
50: Plug placement hole
50a: Inner peripheral surface
50b: Upper opening
50c: Lower opening
55: Plug
55a: Outer peripheral surface
55b: Upper surface
55c: Lower surface
55d: Gas passage
55e: Recess
56: Electric conductor
60: Gas supply path
64a: Ring portion
64b: Gas introduction portion
64c: Distribution portion
70: Compression tester
71: Pedestal
71a: Placement surface
71b: Through hole
72: Cover plate
72a: Insertion hole
73: Punching pin
74: Test piece
90: Metal bonding material
92: Through hole
94: Bonded body

1. A member for a semiconductor manufacturing equipment, comprising:
a ceramic substrate having an upper surface on which a wafer is to be placed and a lower surface;
a plug placement hole that vertically penetrates the ceramic substrate and comprises a tapered inner peripheral surface in which an area of an upper opening is larger than an area of a lower opening;
a ceramic plug comprising a dense outer peripheral surface and a gas passage penetrating the plug, the ceramic plug being embedded such that the dense outer peripheral surface of the plug is directly fitted to the inner peripheral surface of the plug placement hole;
a conductive base plate bonded to the lower surface of the ceramic substrate via a bonding layer; and
a gas supply path that passes through the base plate and the bonding layer to supply gas to the gas passage of the ceramic plug.

2. The member for a semiconductor manufacturing equipment according to claim 1, wherein the inner peripheral surface of the plug placement hole has an inclination angle of 70° or more and 87° or less with respect to the lower opening.

3. The member for a semiconductor manufacturing equipment according to claim 1, wherein the inner peripheral surface of the plug placement hole that is fitted to the dense outer peripheral surface of the ceramic plug is dense.

4. The member for a semiconductor manufacturing equipment according to claim 1, wherein a material constituting the ceramic plug and a material constituting the ceramic substrate both comprise one or more selected from aluminum oxide and aluminum nitride.

5. The member for a semiconductor manufacturing equipment according to claim 1, wherein a porosity of the dense outer peripheral surface of the ceramic plug is 1% or less.

6. The member for a semiconductor manufacturing equipment according to claim 1, wherein the ceramic plug has a truncated conical outer shape.

7. The member for a semiconductor manufacturing equipment according to claim 1, wherein a thickness from the upper opening to the lower opening of the ceramic substrate is 1 mm or more.

8. The member for a semiconductor manufacturing equipment according to claim 1, wherein when the ceramic plug is punched out of the plug placement hole in a direction from the lower opening toward the upper opening of the plug placement hole according to a punching test method described in the specification, a punching strength is 1 N/mm² or more.
